(19) United States
(12) Patent Application Publication
(10) Pub. No.: US 2002/0101227 A1
(43) Pub. Date: Aug. 1, 2002

(54) Dc terminal polarity tester

(76) Inventor: Ysmael Carlos Lopez, Los Angeles, CA (US)

Correspondence Address: Monty Koslover, 145 Via Monte D'oro, Redondo Beach, CA, 90277, US

(21) Appl. No.: 09/769,817

(22) Filed: Jan. 26, 2001

(51) Int. Cl. G01R 31/02

(52) U.S. Cl. 324/72.5

(57) ABSTRACT

A dc terminal polarity tester for use in repairing automotive electrical systems. It is a shirt-pocket sized pen shaped tester, having a probe at one end and a visible bi-color light-emitting diode (LED) at the other end. The tester is provided with a long power lead that includes clips or a connector to connect to a 12 volt dc source. When the tester is connected to a power source, such as an auto battery, the tester probe tip may be touched to a terminal for a polarity check. If the terminal is positive (+), the LED will emit red light. If negative (−), the LED will emit green light. The device may include a buzzer. If so, a positive probed terminal will activate the buzzer in addition to lighting the LED red. The tester is small in size and inexpensive.

### BACKGROUND OF THE INVENTION

1. Field of the Invention

This invention relates to automotive test equipment and in particular to equipment for testing automotive electrical circuitry.

2. Background

When a technician examines an automobile electrical circuit to determine whether any components have failed or have deteriorated, it is standard practice to determine the polarity of a given component or subcircuit terminal connections prior to applying any test voltages. This is done to avoid causing accidental damage to components and subcircuits.

The problem is avoidable where the components are located on removable circuit boards, which can be removed, tested and analyzed using special electrical test equipment. However, in areas where components are soldered in the circuit, identification of terminal polarity must be done on the spot by the repair person.

Over the years, a number of methods and equipments to determine terminal polarity have been in use. The most common being a simple test meter which places a small voltage across a component to determine polarity. There are also a number of electrical circuit testers available, that include a probe which is used to look at any single terminal. These testers are somewhat expensive and are often complex in design. However, at the present time, there does not appear to be available an inexpensive probe type tester that is capable of identifying positive and negative terminal connections on automotive dc circuitry.

### SUMMARY OF THE INVENTION

The invention is a dc terminal polarity tester for use in repairing automotive electrical systems. It is a shirt-pocket sized pen shaped tester, having a probe at one end and a visible bi-colored light-emitting diode (LED) at the other end. A power lead connected to the tester, includes two paralleled resistors which are connected to two power type clips. In use, the power clips are connected to a 12 volt dc source such as the auto battery. The tester probe end is then touched to a terminal for a polarity check. If the terminal is positive (has voltage), the LED will light up red. If negative , the LED will light up green. The device may include a buzzer. If so, a positive probed terminal will activate the buzzer in addition to lighting the LED red.

Accordingly, it is a prime object of this invention to provide a simple, probe type tester that can identify positive and negative terminal polarity on automotive dc circuitry.

Another objective of the invention is to provide a dc polarity tester that is inexpensive.

An advantage of the invention is its small size, which makes it easy to carry and use.

Further objects and advantages of the invention will be apparent from studying the following portion of the specification, the claims and the attached drawings.

### BRIEF DESCRIPTION OF THE DRAWINGS

FIG. 1 is a plan view of the preferred embodiment dc terminal polarity tester according to the present invention, showing a probe holder and attached power leads;

FIG. 2 is a side elevation view of an alternate embodiment of a probe holder portion according to the present invention, particularly showing the addition of a buzzer to the probe holder body;

FIG. 2A is an elevation view of power connector leads that are to be connected to the alternate embodiment probe holder;

FIG. 3 is a circuit diagram of the electrical circuit incorporated in the preferred embodiment invention; and

FIG. 4 is a circuit diagram of the electrical circuit incorporated in the alternate embodiment invention.

### DESCRIPTION OF THE PREFERRED AND ALTERNATE EMBODIMENTS

In the following descriptions, like parts are marked throughout the specification and drawings with the same reference numerals, respectively.

Referring to FIG. 1, there is shown a plan view of the preferred embodiment of a dc terminal polarity tester according to the present invention, showing a probe holder 10 and attached power leads 18. The probe holder 10 is generally tubular in shape and is about the same length as a shirt pocket pen. At one end of the holder 10, a pointed probe tip 14 extends axially and is used for touching a terminal whose polarity is in question. A light emitting diode (LED) 16 is mounted at the holder 10 distal end. This LED 16 is a bi-color emitter and will emit a red or a green color light when activated, depending on how it is biased. A clear, smooth portion 12 of the probe holder 10 ending in a ridge, is provided for grasping the holder with the fingers like a pen.

A long, insulated power lead 18 is connected to an end of the probe holder 10 for supplying dc input power. In the configuration shown in FIG. 1, two resistors 20 are connected in the power lead 18. Alternatively, the resistors 20 could have been contained inside the probe holder 10 which is hollow. Two separate insulated power leads 22 connect to the resistors 20 and to a power connector which is a set of clips 24 used for attaching to auto battery terminals.

Instead of the clips 24, a dc plug connector may be substituted for connection to a 12 vdc socket located on an automobile dashboard. At times, this alternative connector approach may be more convenient, so it is offered as an option.

The dc terminal polarity tester is intended to be used in the following manner: First the clips 24 are attached to the positive and negative terminals of an auto battery. Then the probe holder 10 may be held with its probe tip 14 touching any dc circuit terminal. If the terminal being touched is positive, the LED 16 at the probe holder end will light up showing a red color. If the terminal is negative, the LED 16 will light showing a green color.

The polarity of all the dc terminals can thus be identified quickly and unambiguously in this manner.

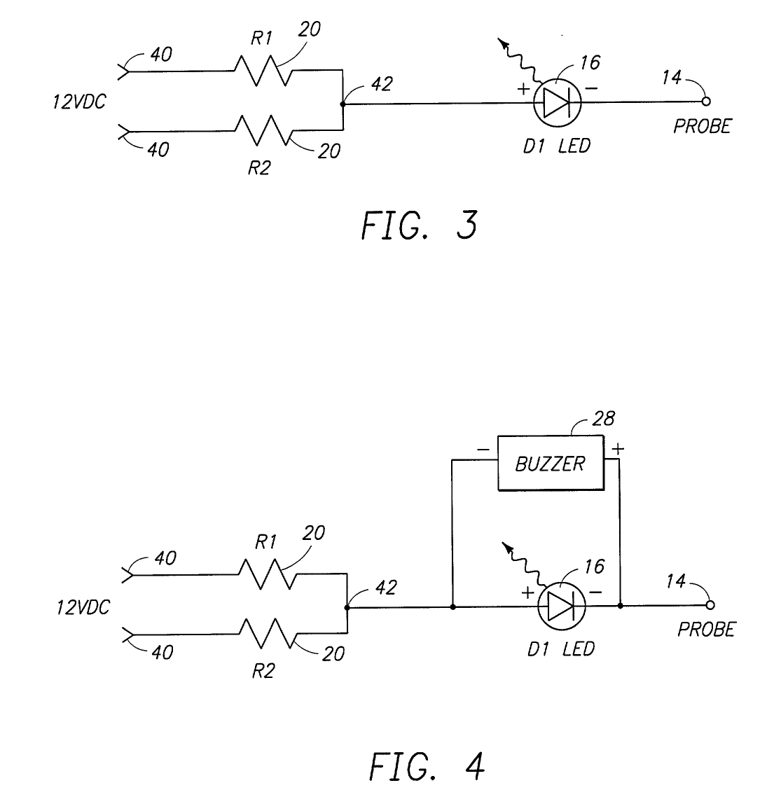

Refer now to FIG. 3 which is a schematic diagram of the electrical circuit which is incorporated in the dc terminal polarity tester device. Other than the clips 24 or a substitute plug connector, the circuit uses only three active components. These are a bi-colored (red/green) LED, D1 and two resistors R1, R2, which are connected by wiring to the clips 24 and to the probe tip 14.

The two resistors R1, R2, 20 are connected in series across input power terminals 40 and are identical, having equally high resistance. A wire lead is connected to the center tap 42 between the resistors R1 and R2 and is connected to the anode of the LED 16; the cathode of the LED 16 being connected to the probe tip 14.

When a 12 vdc voltage source is applied across the power terminals 40, a current of less than 20 milliamps will flow through resistors R1 and R2 and a potential of about 6 vdc will appear at the center tap 42 and at the anode of LED D1.

If the probe tip 14 touches a negative polarity terminal (−), the LED D1 will be forward biased and a few milliamps current will flow through it, causing the LED D1 to emit a green colored light. If the touched terminal has a positive (+) voltage, the LED D1 will be reverse biased and only microamps current will flow, causing the LED D1 to emit a red colored light.

As can be observed, the maximum current and voltage that can be applied by the tester probe tip to any circuit terminal being tested is very low, and should not cause any damage.

A consideration found after producing several of the invention testers, was that in some test situations, the LED light could be obscured at times. This problem could be solved by the addition of a buzzer providing an audible warning sound to indicate a positive voltage at any terminal tested by the probe. Therefore, an alternate embodiment of the invention tester is now described.

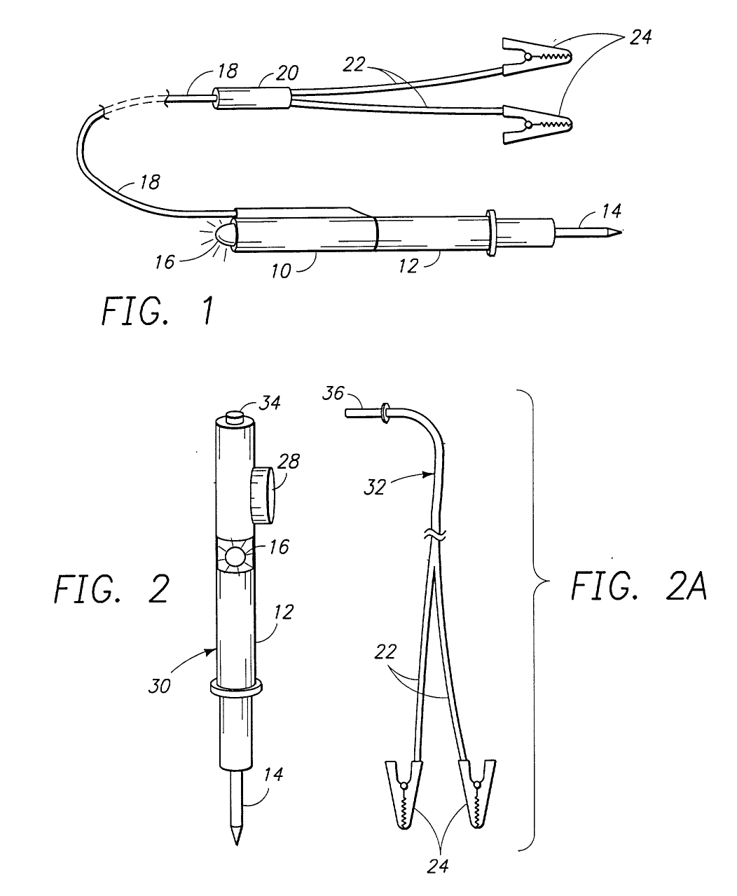

An alternate embodiment of the invention that includes a buzzer is shown in FIGS. 2 and 2A. The changes to the preferred embodiment are mostly of a mechanical and packaging nature. However, the invention electrical circuit described earlier herein in FIG. 3, is unchanged except for the addition of an electrical buzzer 28 as shown in the FIG. 4 schematic diagram. The buzzer 28 is connected across the LED 16, with buzzer positive connected to the LED cathode, so that a terminal testing positive will activate the buzzer.

FIGS. 2 and 2A respectively show an alternate embodiment of probe holder 30 and its matching connector power leads 32. Referring now to FIG. 2, it is seen that the probe holder 30 includes a buzzer 28 and an electrical socket connector 34 at its distal end, the LED 16 having been moved to the side of the holder. Resistors R1 an R2 are now contained within the body of the probe holder 30. A probe tip 14 extends axially at one end of the holder 30 and a smooth, clear area 12 for finger grasping the probe holder 30 is provided near the probe tip 14.

Long power leads 32 at one end, include an electrical plug connector 36 that mates with a socket 34 located at the end of the probe holder 30. At near the distal end of the power leads, the leads are separated 22 and connected to clips 24.

As an alternative, the power leads 32 may be hard-wired to the probe holder 30 instead of being plugged in to the holder end.

As described earlier, an electrical dc plug may be substituted for the clips 24, for use where connection to a dc power socket is more convenient.

The probe holders of the preferred and alternate embodiments are fabricated from a hard, plastic material that is readily available. The device electrical components are few in number, and are standard inexpensive components. Because of its simplicity and low stress operation, the device circuit is expected to be sturdy and reliable. It should also be quite inexpensive to produce in quantity.

From the above description, it is clear that the preferred and alternate embodiments achieve the objects of the present invention. Alternative embodiments and various modifications may be apparent to those skilled in the art. These alternatives and modifications are considered to be within the spirit and scope of the present invention.

What is claimed is:

1. A terminal polarity test device for use in testing a dc electrical circuit, said test device comprising:
(a) a generally tubular shaped probe holder, said probe holder adapted in size and shape for holding like a pencil;
(b) an electrical wired circuit comprising two identical high value resistors connected in series across input dc power terminals; a bi-colored (red/green) light-emitting diode (LED) which is connected at its anode to a center tap between said resistors, and a probe tip which is connected to the cathode of said LED; and
(c) a power connector which is connected by a long insulated cord to said input dc power terminals;
said LED being mounted with its light emitting surface visibly showing at one end of said probe holder, and said probe tip protruding axially from the distal end;
said test device, when said power connector is connected across a low voltage dc power source, displaying a red colored light from said LED if said probe tip is touching a positive polarity dc terminal, and displaying a green colored light from said LED if said probe tip is touching a negative polarity dc terminal.

2. A terminal polarity test device for use in testing a dc electrical circuit, said test device comprising:
(a) a generally tubular shaped probe holder, said probe holder adapted in size and shape for holding like a pencil;
(b) an electrical wired circuit comprising two identical high value resistors connected in series across input dc power terminals; a bi-colored (red/green) light-emitting diode (LED) which is connected at its anode to a center tap between said resistors; an electric buzzer which is connected across said LED, buzzer positive to LED cathode; and a probe tip which is connected to the cathode of said LED; and
(c) a power connector which is connected by a long insulated cord to said input dc power terminals;
said buzzer being mounted on the outer surface of said probe holder; said LED being mounted with its light emitting surface visible at near one end of said probe holder, and said probe tip protruding axially from the holder distal end;
said test device, when said power connector is connected across a low voltage dc power source, visibly showing a red colored light and activating said buzzer if said probe tip is touching a positive polarity dc terminal, and showing a green colored light if said probe tip is touching a negative polarity dc terminal.
